(19) United States
(12) Patent Application Publication
(10) Pub. No.: US 2020/0020563 A1
(43) Pub. Date: Jan. 16, 2020

(54) SUBSTRATE PROCESSING DEVICE, SUBSTRATE PROCESSING METHOD, AND PROGRAM RECORDING MEDIUM

(71) Applicant: SCREEN Holdings Co., Ltd., Kyoto (JP)

(72) Inventors: Takayuki NISHIDA, Kyoto (JP); Junichi ISHII, Kyoto (JP)

(21) Appl. No.: 16/489,736

(22) PCT Filed: Feb. 20, 2018
(86) PCT No.: PCT/JP2018/005987

§ 371 Date: Aug. 29, 2019

(30) Foreign Application Priority Data
Mar. 27, 2017 (JP) 2017-061401

(51) Int. Cl. H01L 21/687; B08B 1/00; B08B 1/02; H01L 21/02; H01L 21/67

(52) U.S. Cl. CPC H01L 21/68721; B08B 1/002; H01L 21/67046; H01L 21/02057; B08B 1/02

(57) ABSTRACT

A substrate processing apparatus performs brush cleaning of a substrate. The substrate processing apparatus includes a spin base provided rotatably about a rotation axis, a spin base rotation mechanism that rotates the spin base, and a plurality of first chuck pins provided in the spin base, the first chuck pins being switchable between an opened state and a closed state and capable of clamping an end portion of the substrate from a side surface thereof in the closed state. An upper surface of each of the plurality of first chuck pins has a height the same as or lower than an upper surface of the substrate in the closed state where the end portion of the substrate is clamped.

### TECHNICAL FIELD

The present invention relates to a substrate processing apparatus and a substrate processing method to perform processing using a processing liquid on substrates to be processed. Further, the present invention relates to a program recording medium in which a program to execute substrate processing by a substrate processing apparatus is recorded. The substrates to be processed include various substrates such as semiconductor wafers, glass substrates for liquid crystal displays, glass substrates for plasma displays, substrates for photomasks, substrates for optical disks, substrates for magnetic disks, and substrates for magneto-optical disks.

### BACKGROUND ART

One of the processing steps of a substrate is a step of cleaning a front surface of the substrate by supplying a processing liquid to the front surface of the substrate. In a case where a cleaning object is not sufficiently achieved only with supply of the processing liquid, a brush cleaning step of cleaning the front surface of the substrate by applying a brush to the front surface of the substrate is performed.

In a so-called single substrate processing type cleaning apparatus that performs substrate cleaning process by rotating a substrate while holding the substrate horizontally, upon supplying a processing liquid to a front surface of the substrate, a brush is applied to the front surface of the substrate, and cleaning process by the brush is implemented.

When brush cleaning is performed in a so-called single substrate processing type substrate processing apparatus in which a substrate is held parallel to a horizontal surface and processes a substrate in one processing chamber one by one, the substrate is held on a spin base, and by integrally rotating the substrate and the spin base and by abutting a brush with the substrate, the brush cleaning is performed. A method in which a spin base holds a substrate includes a suction chuck method of suctioning and holding one of principal surfaces of the substrate, and an edge holding method of clamping an end portion (around a bevel or an edge) of the substrate from a side surface of the substrate. In the suction chuck method illustrated in Patent Literature 1, while the end portion of the substrate can be freely cleaned with a brush, there is a problem that a suction mark is left on the substrate, a portion where a suction chuck and the substrate are in contact cannot be cleaned at the time of suctioning, etc. The edge holding method is capable of cleaning portions other than the end portion of the substrate unlike the suction chuck method, and is widely used.

In particular, in a substrate rear surface cleaning step, by nature of the step, the edge holding method is used in most cases.

However, since chuck pins hold the end portion of the substrate for holding the substrate of the edge holding method, there is a problem that brush cleaning of the end portion of the substrate becomes difficult.

In order to handle this problem, a method in which some of the plurality of chuck pins that hold an end portion of a substrate are appropriately retracted, and a brush is brought into a portion of the end portion of the substrate from which the chuck pins are retracted and performs brush cleaning is proposed. A technology example in which some of chuck pins are retracted as explained above is described in Patent Literature 2.

In Patent Literature 2, although a substrate is held by the edge holding method, chuck pins are retracted so that a brush and the chuck pins are not brought into contact with each other, and brush cleaning of a principal surface of the substrate is synchronized with this retraction. Regarding a point from which the chuck pins are retracted, the brush is horizontally moved to a position exceeding an edge of the substrate, and so-called brush over-scanning is performed.

### CITATION LIST

### Patent Literature

Patent Literature 1: Japanese Patent Application Publication No. 2016-152274

Patent Literature 2: Japanese Patent No. 4939376

### SUMMARY OF THE INVENTION

### Technical Problem

In the brush over-scanning illustrated in Patent Literature 2, there is a need for successively opening and closing the chuck pins in synchronization with rotation of the substrate so that the brush is not brought into contact with the chuck pins rotated together with the substrate. Therefore, there is a need for performing complicated synchronous control during the cleaning process. If the synchronous control is failed, there is a possibility that a processing apparatus and the substrate are damaged. In the brush over-scanning illustrated in Patent Literature 2, at least some of the chuck pins hold the substrate in a state where the chuck pins project at a higher position than the substrate during substrate cleaning. Thus, a cleaning liquid collides with the chuck pins and the liquid scatters, and causes particles to be generated.

Therefore, there is a need for an apparatus and/or a method in which a front surface and a bevel portion of a substrate are favorably cleaned in a simple control method and/or a simple apparatus arrangement while holding the substrate by the edge holding method.

A preferred embodiment of the prevent invention provides an apparatus and/or a method in which a front surface and a bevel portion of a substrate are favorably cleaned in a simple control method and/or a simple apparatus arrangement while adopting a holding method by the so-called edge holding method of clamping an end portion of the substrate.

### Solution to Problem

A preferred embodiment of the present invention provides a substrate processing apparatus that performs brush cleaning of a substrate. The substrate processing apparatus includes a spin base provided rotatably about a rotation axis, a spin base rotation mechanism that rotates the spin base, and a plurality of first chuck pins provided in the spin base, the first chuck pins being switchable between an opened state and a closed state and capable of clamping an end portion of the substrate from a side surface thereof in the closed state. An upper surface of each of the plurality of first chuck pins is arranged to have a height the same as or lower than an upper surface of the substrate in the closed state where the end portion of the substrate is clamped.

With this arrangement, it is possible to perform edge over-scanning by a brush without contact between the brush and the chuck pins.

In a preferred embodiment of the present invention, the substrate processing apparatus further includes a plurality of second chuck pins provided in the spin base, the second chuck pins being switchable between an opened state and a closed state and capable of clamping an end portion of the substrate from a side surface thereof in the closed state. An upper surface of each of the plurality of second chuck pins is arranged to have a height higher than the upper surface of the substrate in the closed state where the end portion of the substrate is clamped.

In a preferred embodiment of the present invention, it is arranged such that each of the first chuck pins has an abutting surface to be abutted with the substrate in the closed state, and the abutting surface is abuttable with at least a lower surface and a side surface of a peripheral edge portion of the substrate.

A preferred embodiment of the present invention provides a substrate processing method that performs brush cleaning of a substrate. The substrate processing method includes a first clamping step of clamping a substrate by a plurality of first chuck pins provided in a spin base, the first chuck pins being switchable between an opened state and a closed state and capable of clamping an end portion of the substrate from a side surface thereof in the closed state, and a second clamping step of clamping a substrate by a plurality of second chuck pins provided in the spin base, the second chuck pins being switchable between an opened state and a closed state and capable of clamping an end portion of the substrate from a side surface thereof in the closed state. An upper surface of each of the plurality of first chuck pins is arranged to have a height the same as or lower than an upper surface of the substrate in the closed state where the end portion of the substrate is clamped. An upper surface of each of the plurality of second chuck pins is arranged to have a height higher than the upper surface of the substrate in the closed state where the end portion of the substrate is clamped.

In a preferred embodiment of the substrate processing method, in the first clamping step, substrate cleaning is performed by a brush.

In a preferred embodiment of the substrate processing method, in the first clamping step, the spin base is rotated at first rotational speed, and in the second clamping step, the spin base is rotated at rotational speed higher than the first rotational speed.

A preferred embodiment of the present invention provides a program recording medium of a program to execute a substrate processing method that performs brush cleaning of a substrate. The substrate processing method includes a first clamping step of clamping a substrate by a plurality of first chuck pins provided in a spin base, the first chuck pins being switchable between an opened state and a closed state and capable of clamping an end portion of the substrate from a side surface thereof in the closed state, and a second clamping step of clamping a substrate by a plurality of second chuck pins provided in the spin base, the second chuck pins being switchable between an opened state and a closed state and capable of clamping an end portion of the substrate from a side surface thereof in the closed state. An upper surface of each of the plurality of first chuck pins is arranged to have a height the same as or lower than an upper surface of the substrate in the closed state where the end portion of the substrate is clamped. An upper surface of each of the plurality of second chuck pins is arranged to have a height higher than the upper surface of the substrate in the closed state where the end portion of the substrate is clamped.

In a preferred embodiment of the program recording medium, in the first clamping step of the substrate processing method, substrate cleaning is performed by a brush.

In a preferred embodiment of the program recording medium, in the first clamping step of the substrate processing method, the spin base is rotated at first rotational speed, and in the second clamping step, the spin base is rotated at rotational speed higher than the first rotational speed.

The aforementioned and other objects, features, and effects of the present invention will be clarified by the following description of a preferred embodiment with reference to the accompanying drawings.

### BRIEF DESCRIPTION OF THE DRAWINGS

FIG. 1 is a side view schematically showing an arrangement of a substrate processing apparatus according to a preferred embodiment.

FIG. 2 is a side view schematically showing an arrangement of a processing liquid supply mechanism 200 according to the preferred embodiment.

FIG. 3 is a block diagram schematically showing an arrangement of a controller 100 according to the preferred embodiment.

FIG. 4 is a schematic side view for explaining structures of chuck pins CA and CB according to the preferred embodiment.

FIG. 5 is a schematic plan view for explaining an action of the chuck pins CA and CB according to the preferred embodiment.

FIG. 6 is a schematic plan view for explaining an action of the chuck pins CA and CB according to the preferred embodiment.

FIG. 7 is a schematic plan view for explaining an action of the chuck pins CA and CB according to the preferred embodiment.

FIG. 8 is a schematic plan view for explaining an action of the chuck pins CA and CB according to the preferred embodiment.

FIG. 9 is a flowchart of processing according to the preferred embodiment.

### DETAILED DESCRIPTION OF PREFERRED EMBODIMENTS

Hereinafter, an arrangement and actions of a substrate processing apparatus 1 will be described based on the drawings.

In the drawings, the same reference signs will be given to portions having similar arrangements and similar functions, and description thereof shall be omitted below. Each of the figures is a schematic illustration.

### <Arrangement of Substrate Processing Apparatus 1>

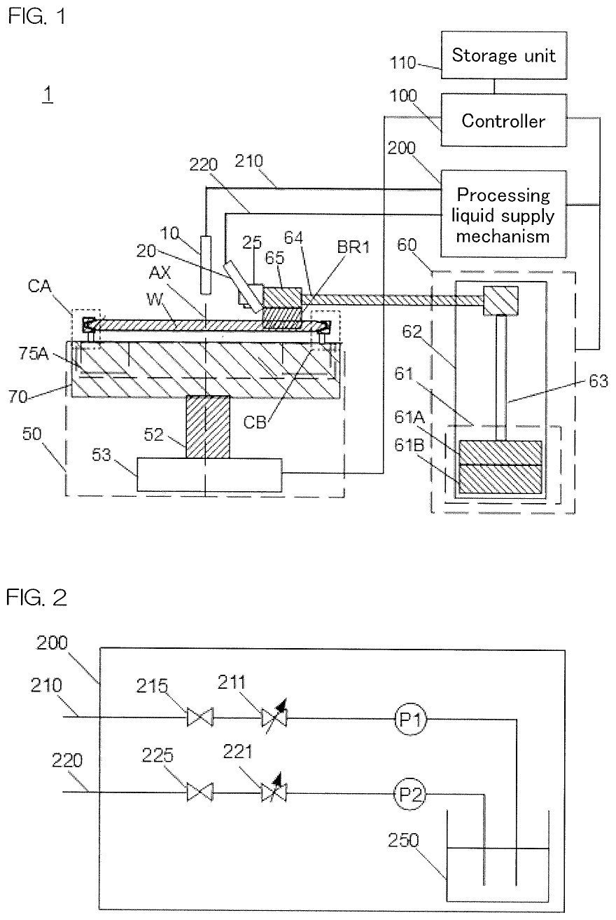

FIG. 1 is a schematic view showing an example of the arrangement of the substrate processing apparatus 1 according to a preferred embodiment.

First, various members and mechanisms forming the substrate processing apparatus 1 will be described.

The substrate processing apparatus 1 includes a spin chuck 50 to hold and rotate a substrate W. The spin chuck includes a substantially disc-shaped spin base 70, a columnar support shaft 52 coupled to the lower side of the spin base 70, and a spin base rotation mechanism 53 coupled to the support shaft 52. The spin base rotation mechanism 53 rotates the spin base 70 about a spin base rotation axis AX by rotating the support shaft 52.

In a peripheral edge portion of an upper surface of the spin base 70, a plurality of chuck pins CA and a plurality of chuck pins CB to hold the substrate W from a peripheral edge of the substrate are placed alternately at substantially equal intervals in the circumferential direction of the upper surface of the spin base 70. An upper portion of each of the chuck pins CA is arranged to have a height higher than an upper surface of the substrate W. An upper portion of each of the chuck pins CB is arranged to have the same height as or lower than the upper surface of the substrate W.

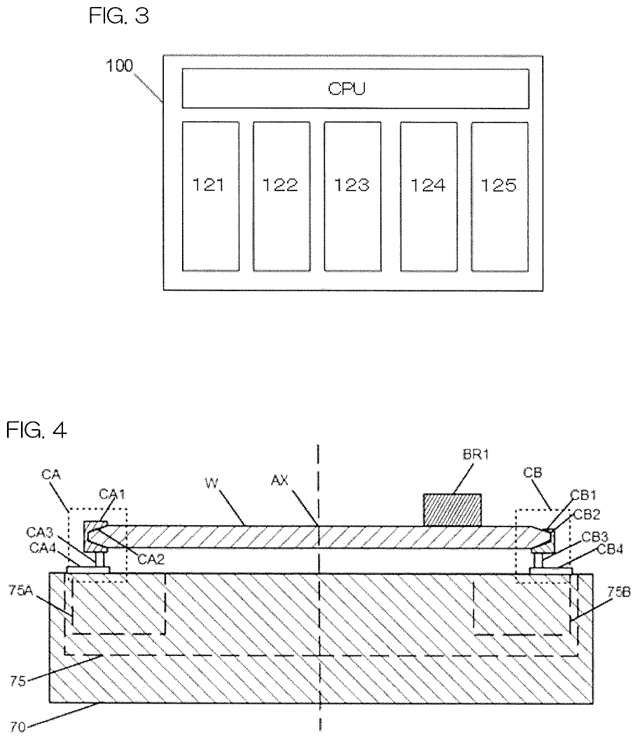

Inside the spin base 70, chuck pin movement mechanisms 75A and 75B shown by dotted lines are stored. The chuck pin movement mechanism 75A realizes an action of switching the plurality of chuck pins CA between an opened state and a closed state. The chuck pin movement mechanism 75B realizes an action of switching the plurality of chuck pins CB between an opened state and a closed state. These actions are realized by control signals from an arm movement mechanism control unit 122 in a controller 100 (see FIG. 3).

An arm movement mechanism 60 is installed on the side of the spin chuck 50. The arm movement mechanism 60 includes a mover portion 61 having an axis rotation mechanism 61A to pivot and move an arm 64 in a horizontal plane, and an elevating/lowering mechanism 61B to elevate the arm 64 in the vertical direction. The mover portion 61 includes a cover 62 to cover a periphery of the mover portion 61 in order to shield contaminants generated from the mover portion 61. The mover portion 61 may include a forward/rearward movement mechanism (not shown) to move a head 65 and a brush BR1 forward/rearward in the long axis direction of the arm 64 in place of the axis rotation mechanism 61A or in addition to the axis rotation mechanism 61A.

The mover portion 61 is coupled to a support shaft 63 extending in the vertical direction, and the support shaft 63 is further coupled to the arm 64 extending in the horizontal direction. One end of the arm 64 is coupled to the head 65. A first brush BR1 is fixed on the head 65. By moving the head 65 by the arm movement mechanism 60, a position of the first brush BR1 can be moved. The head 65 may be coupled to a second nozzle 20 through a fixing tool 25 as shown in FIG. 1.

The substrate processing apparatus 1 further includes a first nozzle 10 and the second nozzle 20 to supply processing liquids to the substrate W held by the spin chuck 50.

### <Arrangement of Processing Liquid Supply Mechanism 200>

Hereinafter, with reference to FIG. 2 appropriately in addition to FIG. 1, a layout arrangement of the first nozzle and the second nozzle and an arrangement of a processing liquid supply mechanism 200 will be described. FIG. 2 is a side view schematically showing the arrangement of the processing liquid supply mechanism 200 according to the preferred embodiment.

The first nozzle 10 is arranged to being capable of discharging the processing liquid supplied from the processing liquid supply mechanism 200 through a pipe 210 from a discharge port 10A. In the present preferred embodiment, the first nozzle 10 is fixed to an upper portion of the substrate W by a fixing tool (not shown) so that the processing liquid is discharged toward the center of a principal surface (upper surface) of the substrate W.

A fixing position of the first nozzle 10 is set at such a height that the first nozzle 10 is not brought into contact with the second nozzle 20 and the head 65 in accordance with movement of the second nozzle 20 and the head 65.

The layout arrangement of the first nozzle 10 is just an example. As an arrangement to discharge the processing liquid toward the center of the principal surface (upper surface) of the substrate W, various exemplified arrangements are considered including an arrangement in which a so-called shielding plate opposing the principal surface of the substrate W is disposed above the substrate W and the discharge port of the first nozzle 10 is disposed in the center of the shielding plate. The first nozzle 10 may be arranged to be movable along the principal surface (upper surface) of the substrate W by combining with various movement mechanisms, and disposed along on the rotation axis of the substrate W when the processing liquid is discharged toward the center of the principal surface (upper surface) of the substrate W, and retracted to a retracted position at other times. The discharge port of the first nozzle 10 may be arranged to be disposed not on the rotation axis of the substrate W and the processing liquid may be discharged obliquely toward the center of the principal surface (upper surface) of the substrate W.

The first nozzle 10 is connected to the processing liquid supply mechanism 200 whose details are shown in FIG. 2 through the pipe 210. The processing liquid supply mechanism 200 supplies the processing liquid stored in a processing liquid tank 250 to the first nozzle 10 through the pipe 210 by a pump P1. A flow rate adjustment valve 211 to adjust a flow rate of the processing liquid and an on-off valve 215 to open/close the pipe 210 are interposed in the pipe 210. The flow rate of the processing liquid discharged from the first nozzle 10 is regulated by adjusting an output of the pump P1 and an opening degree of the flow rate adjustment valve 211, and discharge of the processing liquid is started/ended by opening/closing the on-off valve 215.

The second nozzle 20 is arranged to be capable of discharging the processing liquid supplied from the processing liquid supply mechanism 200 through a pipe 220 from a discharge port 20A. The processing liquid supply mechanism 200 supplies the processing liquid stored in the processing liquid tank 250 to the second nozzle 20 through the pipe 220 by a pump P2. A flow rate adjustment valve 221 to adjust a flow rate of the processing liquid flowing through the pipe 220 and an on-off valve 225 to open/close the pipe 220 are interposed in the pipe 220. The flow rate of the processing liquid discharged from the second nozzle 20 is regulated by adjusting an output of the pump P2 and an opening degree of the flow rate adjustment valve 221, and discharge of the processing liquid is started/ended by opening/closing the on-off valve 225.

The second nozzle 20 is fixed to the head 65 through the fixing tool 25, and moved together with the head 65, that is, the brush BR1. The main role of the second nozzle 20 is, when the brush BR1 is abutted with the substrate W, that is, when the principal surface (upper surface) of the substrate W is cleaned by the brush BR1, to replenish the processing liquid to a rotation downstream adjacent region adjacent to the substrate rotation downstream side with respect to an abutment region where the brush BR1 and the substrate W are abutted, and to avoid a processing liquid film runout or a decrease in thickness of the processing liquid film in the rotation downstream adjacent region. Therefore, the second nozzle 20 is fixed to the head 65 through the fixing tool 25 with regulating a positional relationship between the brush BR1 and the second nozzle 20, an angle of the second nozzle 20, etc., so that the processing liquid is discharged toward a position of the rotation downstream adjacent region from the discharge port 20A.

More specifically speaking, the second nozzle 20 is fixed to a side surface of the head 65 at an angle from the long axis thereof (for example, at 45 degrees to 80 degrees with respect to the rotation axis of the spin base 70 from the lower side of the rotation axis) so that the processing liquid is discharged obliquely downward with respect to the spin base 70. A film thickness decrease region where film thickness of the processing liquid is small is typically generated on the substrate rotation downstream side of the abutment region where the brush BR1 and the substrate W are abutted. More specifically, the film thickness decrease region is formed in a shape starting from an edge on the substrate rotation downstream side among an edge of a lower surface of the brush BR1 (downstream side edge of the brush BR1) and slightly extending from the edge to the substrate rotation downstream side. Therefore, a target position where the processing liquid is discharged from the second nozzle 20 is desirably set in the vicinity of a side surface of the brush BR1 and on the rotation downstream side, and further, desirably set at a position so that the processing liquid replenished from the second nozzle 20 flows to the entire film thickness decrease region.

Among the substrate rotation downstream side of the abutment region, the processing liquid film thickness is decreased the most in the vicinity of a border line of the abutment region. Therefore, the second nozzle is desirably fixed to the head 65 so that part of the processing liquid from the second nozzle 20 flows in the vicinity of the border line of the abutment region.

As shown in FIG. 2, it may be arranged such that the pipe 210 and the pipe 220 are independently coupled to the common processing liquid tank 250, or it may be formed such that the pipe 210 and the pipe 220 join together to a common pipe (not shown) before reaching the processing liquid tank 250 and then the processing liquid tank 250 and the common pipe are connected. The pipes may be coupled different processing liquid tanks 250A, 250B (not shown), respectively.

### <Controller 100>

With reference to FIGS. 1 and 3, an arrangement of the controller 100 will be described.

FIG. 3 is a block diagram schematically showing the arrangement of the controller 100 according to the preferred embodiment.

The substrate processing apparatus 1 further has the controller 100. The controller 100 controls actions of the chuck pin movement mechanisms 75A and 75B, the spin base rotation mechanism 53, the mover portion 61 of the arm movement mechanism 60, the pumps P1 and P2, the flow rate adjustment valves 211 and 221, and the on-off valves 215 and 225 of the processing liquid supply mechanism 200, etc.

The controller 100 includes a CPU 120, a processing liquid supply mechanism control unit 121, the arm movement mechanism control unit 122, a chuck pin movement mechanism control unit 123, a spin base rotation mechanism control unit 124, and an other-mechanism control unit 125 (see FIG. 3).

A storage unit 110 connected to the controller 100 stores recipes in which the procedure of processing steps, apparatus control parameters required for implementing the steps, etc., are stored, and various algorithms for calculating values of the apparatus control parameters and control signals for each operator command information or each step. Each of the above control units calculates the value of the control signal in cooperation with the storage unit 110, and sends the control signal according to an advancing state of the processing steps of the apparatus to the portion to which the control unit is connected. The controller 100 has a mode of a computer. The storage unit 110 is an example of a program recording medium in which a program to be executed by the controller 100 is recorded.

In order to avoid splashing of the processing liquid and contamination of the atmosphere in accordance with processing of the substrate W, the controller 100 may be arranged to be provided outside a partition wall (not shown) provided between the controller 100 and the spin chuck 50, the partition wall that covers the spin chuck 50, etc., and communicates with the various mechanisms described above through wires to send and receive the control signals.

### <Structures of Chuck Pins CA and CB>

FIG. 4 is a schematic side view for explaining structures of the chuck pins CA and CB according to the preferred embodiment. In FIG. 4, for simplifying, the storage unit 110, the controller 100, the processing liquid supply mechanism 200, the first nozzle 10, the second nozzle 20, and the arm movement mechanism 60 are omitted from the figure.

The chuck pins CA and the chuck pins CB are different from each other whether the upper surface of the chuck pin is at a position higher than the upper surface of the substrate W or not when the chuck pins are abutted with the substrate W.

Hereinafter, with reference to FIG. 4, structures of the chuck pin movement mechanisms 75A and 75B and the chuck pins CA and CB will be described in detail.

FIG. 4 shows only the spin base 70 among the spin chuck 50 for the sake of simplicity. Inside the spin base 70, a chuck pin movement mechanism 75 shown by a dotted line in FIG. 4 is incorporated. The chuck pin movement mechanism 75 has the chuck pin movement mechanism 75A and the chuck pin movement mechanism 75B.

The chuck pin movement mechanism 75A is stored below each of the plurality of chuck pins CA in the spin base 70, and activated by the control signal by the chuck pin movement mechanism control unit 123 in the controller 100.

By moving a support shaft CA3 of each of the chuck pins CA along a slot CA4, the chuck pin movement mechanism 75A moves a chuck pin main body CA1 coupled to the support shaft CA3. By the movement, two states of an “opened state” where an abutting surface CA2 of the chuck pin CA is not abutted with an edge or a bevel of the substrate W and a “closed state” where the abutting surface CA2 is abuttable with the edge or the bevel of the substrate W are realized. The movement by the chuck pin movement mechanism 75A is realized, for example, by the chuck pin movement mechanism 75A moving the support shaft CA3 horizontally along the radial direction of the upper surface of the spin base 70 along the slot CA4 which is made by forming a groove along the radial direction of the upper surface of the spin base 70.

Regarding the movement by the chuck pin movement mechanism 75A, abutment or separation of the abutting surface CA2 with or from the substrate W may be realized by another aspect, for example, by rotating the support shaft CA3 about the axis provided in the horizontal direction along the tangent direction around the substrate W below the support shaft CA3. As a mechanical arrangement of the chuck pin movement mechanism 75A to move the support shaft CA3 and realize the opened state and the closed state of the chuck pin CA, various arrangements such as an arrangement in which displacement of members is realized by a cam mechanism and an arrangement in which displacement of members is realized without any contact by utilizing magnets are conventionally known, and any arrangements may be used.

Next, the chuck pin movement mechanism 75B will be described. The chuck pin movement mechanism 75B is stored below each of the plurality of chuck pins CB in the spin base 70, and activated by the control signal by the chuck pin movement mechanism control unit 123 in the controller 100. Regarding the other arrangements, the chuck pin movement mechanism 75B has similar arrangements to the chuck pin movement mechanism 75A.

Since the chuck pin movement mechanisms 75A, 75B serving as independent movement mechanisms are respectively coupled to the plurality of chuck pins CA, CB, it is possible to move the plurality of chuck pins CA and CB respectively independently.

With reference to FIG. 4 continuously, the arrangement of the chuck pins CA and CB will be described.

The chuck pin CA has the chuck pin main body CA1, the abutting surface CA2 to be abutted with the substrate W on a side surface of the chuck pin main body CA1, the slot CA4 provided in a peripheral edge portion of the upper surface of the spin base 70, and the support shaft CA3 connecting the slot CA4 and a lower surface of the chuck pin main body CA1.

As schematically shown in FIG. 4, in a state where the chuck pin CA is abutted with the substrate W, the upper surface of the chuck pin CA is placed at a position higher than the upper surface of the substrate W.

The abutting surface CA2 may form a part of the chuck pin main body CA1 or may be a member independent from the chuck pin main body CA1. That is, the chuck pin main body CA1 and the abutting surface CA2 may be independent members or may be an integrally formed member.

Since the abutting surface CA2 is brought into direct contact with an end surface of the substrate W, a material is determined in consideration of the likelihood of contamination, chemical resistance, durability, etc. The chuck pin CA is required to reliably hold the substrate W by abutting the abutting surface CA2 with the end surface of the substrate W. Therefore, a material or a front surface shape with which frictional force hardly acts when the chuck pin is abutted with the substrate W is not desirable. As a material of the abutting surface CA2, for example, a sponge material (porous member) made of an elastically deformable material such as PVA (polyvinyl alcohol) and urethane is selected.

Successively, the chuck pins CB will be described.

The chuck pin CB has a chuck pin main body CM, an abutting surface CB2 to be abutted with the substrate W on a side surface of the chuck pin main body CM, a slot CB4 provided in the peripheral edge portion of the upper surface of the spin base 70, and a support shaft CB3 connecting the slot CB4 and a lower surface of the chuck pin main body CM.

As schematically shown in FIG. 4, in a state where the chuck pin CB is abutted with the substrate W, the upper surface of the chuck pin CB is placed at the lower position than the upper surface of the substrate W.

The abutting surface CB2 may form a part of the chuck pin main body CM or may be a member independent from the chuck pin main body CM. That is, the chuck pin main body CM and the abutting surface CB2 may be independent members or may be an integrally formed member.

Since the abutting surface CB2 is brought into direct contact with the end surface of the substrate W, a material is determined in consideration of the likelihood of contamination, chemical resistance, durability, etc. The chuck pin CB is required to reliably hold the substrate W by abutting the abutting surface CB2 with the end surface of the substrate W. Therefore, a material or a front surface shape with which frictional force hardly acts when the chuck pin is abutted with the substrate W is not desirable. As a material of the abutting surface CB2, for example, a sponge material (porous member) made of an elastically deformable material such as PVA (polyvinyl alcohol) and urethane is selected.

In the present preferred embodiment, the abutting surface CA2 or CB2 is arranged such that as shown in FIG. 4, by recessing a side surface opposing the end portion (around the bevel or the edge) of the substrate W toward the outside in the radial direction of the substrate, substantially all the end portion of the substrate W is clamped from the upper and lower sides and the side surface.

The shape of the abutting surface CA2 or CB2 is not limited to such a shape but may take various modes as long as a function of holding the substrate W can be properly exerted. For example, the abutting surface CA2 may be formed in a chair shape including a mounting surface that supports the end portion of the substrate W from a lower portion, and flat plate-shaped side surfaces extending from the mounting surface in the vertical direction, in which the mounting surface and the side surfaces are abutted with the end portion of the substrate W. The shape of the abutting surface CB2 can take various modes as long as the function of holding the substrate W is exerted and the shape is suitable for brush cleaning of the end portion of the substrate W.

The apparatus arrangement of the substrate processing apparatus 1 is described above.

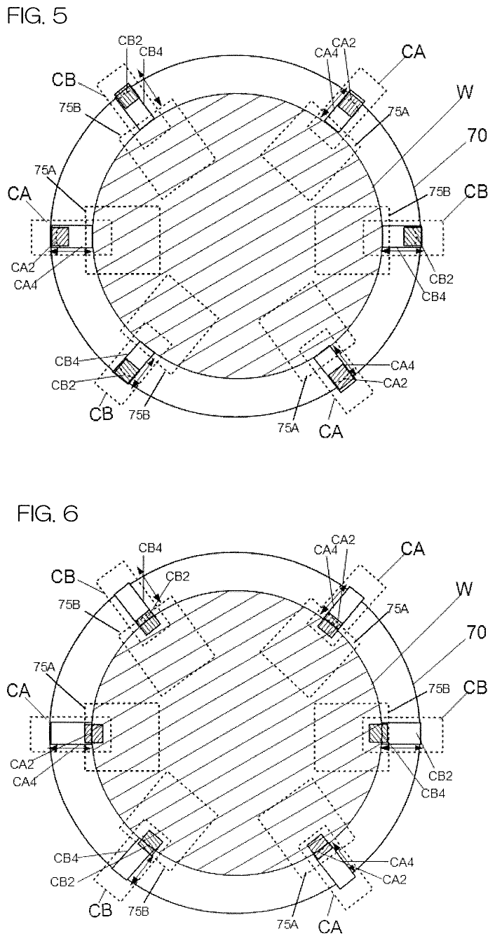

Next, with reference to FIGS. 5 to 8, actions of the chuck pins CA and CB will be described.

All of FIGS. 5 to 8 are schematic plan views for explaining the actions of the chuck pins CA and CB according to the preferred embodiment.

### <Case Where Both Chuck Pins CA and CB are in Opened State>

FIG. 5 is a schematic plan view for explaining the action of the chuck pins CA and CB according to the preferred embodiment. FIG. 5 is a schematic view of a case where both the chuck pins CA and CB are in the opened state.

The plurality of chuck pins CA and the plurality of chuck pins CB are disposed alternately in the circumferential direction above the spin base 70 as illustrated in FIG. 5. Since there is a need for being capable of clamping the substrate W by only one of the plurality of chuck pins CA and the plurality of chuck pins CB, at least three chuck pins CA and three chuck pins CB are required. However, more chuck pins such as six chuck pins CA and six chuck pins CB may be provided.

As already described, the chuck pins CA and the chuck pins CB are movable between the “opened state” and the “closed state” by the chuck pin movement mechanism 75A and by the chuck pin movement mechanism 75B, respectively and independently.

FIG. 5 shows a state where the plurality of chuck pins CA are moved in the “opened state, ” that is, to the radially outward direction of the spin base 70, and the plurality of chuck pins CB are also moved in the “opened state,” that is, to the radially outward direction of the spin base 70. In FIG. 5, for the purpose of showing a positional relationship between the substrate W and the chuck pins, the substrate W is illustrated and oblique lines are drawn for clarification. However, the illustration of the substrate W is only for reference showing the positional relationship.

### <Case Where Both Chuck Pins CA and CB are in Closed State>

FIG. 6 is a schematic plan view similar to FIG. 5. In FIG. 6, all of the plurality of chuck pins CA and CB are in the “closed state.”

### <Case Where Only Chuck Pins CA are in Closed State>

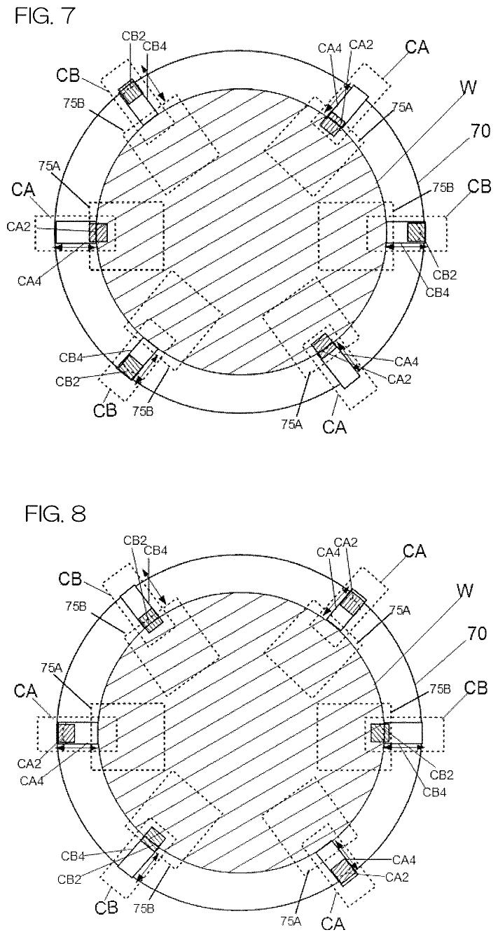

FIG. 7 is also a schematic plan view similar to FIG. 5. In FIG. 7, the plurality of chuck pins CA are in the “closed state,” whereas the plurality of chuck pins CB are in the “opened state.”

At this time, the substrate W is clamped only by the plurality of chuck pins CA.

### <Case Where Only Chuck Pins CB are in Closed State>

FIG. 8 is also a schematic plan view similar to FIG. 5. In FIG. 8, the plurality of chuck pins CA are in the “opened state,” whereas the plurality of chuck pins CB are in the “closed state.”

At this time, the substrate W is clamped only by the plurality of chuck pins CB.

In this state, the height of the upper surfaces of the chuck pins CB is lower than the height of the upper surface of the substrate W. Thus, when the bevel of the substrate W is cleaned by the brush BR1, the brush BR1 does not collide with the chuck pins CB in the bevel of the substrate W. Therefore, it is possible to execute brush over-scanning without performing complicated control such as control of switching the chuck pins.

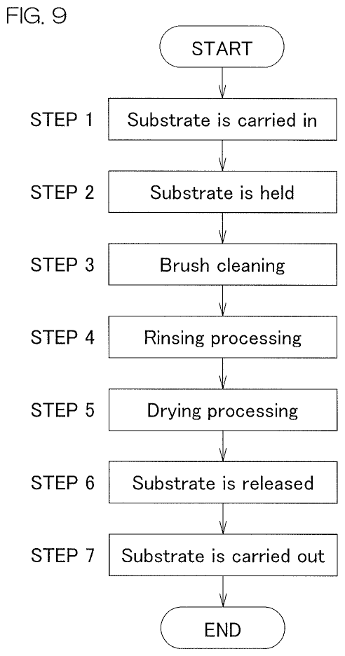

Next, with reference to FIG. 9, an action example of the substrate processing apparatus 1 will be described.

FIG. 9 is a flowchart of processing according to the preferred embodiment.

### <STEP 1: Carry-in of Substrate>

First, in order to add predetermined processing to the substrate W, the substrate W is held by the spin chuck 50. The substrate W is transferred to the substrate processing apparatus 1 by a substrate transfer mechanism (not shown).

At this time, the chuck pins CA and CB are in the opened state which is already described, that is, the state shown in FIG. 5.

The substrate transfer mechanism moves the substrate W based on position information already stored in the storage unit 110. More specifically, the substrate transfer mechanism horizontally moves the substrate W to a position where the end surface of the substrate W can be held by the chuck pins CA and CB, in other words, to a position where the end surface of the substrate W opposes all the abutting surfaces CA2 and CB2 of the chuck pins CA and CB.

In this stage, the spin base 70 stops rotating.

### <STEP 2: Holding of Substrate>

In STEP 2, the chuck pins CA and the chuck pins CB are brought into the “closed state.” That is, the chuck pins are brought into the state schematically shown in FIG. 6. As a result, the end portion (the bevel or the edge) of the substrate W is held by the chuck pins CA and CB. By holding the substrate W by all the chuck pins, the substrate W is held in a state where the substrate W has little eccentricity with respect to the spin base 70.

<STEP 3: Start of Rotation of Substrate subjected to Brush Cleaning>

Next, only the chuck pins CA are brought into the “opened state.” That is, the chuck pins are brought into the state schematically shown in FIG. 8. In this state, the spin base 70 starts rotating. In the present preferred embodiment, speed of the spin base 70 can be switched between at least four stages including “stop,” “low speed,” “middle speed,’ and “high speed.” For example, rotational speed of “low speed” ranges from several tens to several hundreds of rpm, rotational speed of “middle speed” ranges from several hundreds to 1,000 rpm, and rotational speed of “high speed” ranges from 1,000 to 3,000 rpm.

In STEP 3, the spin base 70 is accelerated up to the low rotational speed.

Next, the processing liquid favorable for brush cleaning is discharged from the nozzle 10 in the vicinity of the central upper side of the substrate W onto the principal surface of the substrate W. The processing liquid spreads to the radially outward direction of the substrate W by centrifugal force in accordance with rotation of the substrate W. As the processing liquid in brush processing, deionized water is mainly used. However, depending on required contents of substrate processing, a cleaning liquid such as carbonated water of low concentration, weak ozone water, SC1, SC2, and FOM may be used.

Next, the brush cleaning by the brush BR1 illustrated in FIGS. 1 and 4 is performed. The brush BR1 is slidingly moved on the principal surface of the substrate W by horizontally moving the head 65 coupled to the brush BR1 along and above the principal surface of the substrate W by the arm movement mechanism 60. A sliding movement range runs from the substrate center on the principal surface of the substrate W to the vicinity of a peripheral edge portion of the substrate. Even when the brush BR1 is moved to the peripheral edge portion of the substrate, the brush BR1 and the chuck pins CB are not brought into contact with each other. Therefore, for all the upper surface of the substrate W from the substrate center to the peripheral edge portion of the substrate, it is possible to implement the brush cleaning without caring contact with the chuck pins.

Particles, dirt, etc., on the principal surface of the substrate W are brush-cleaned by the brush BR1, and the particles, etc., removed from the substrate W by the brush BR1 flow down to the outside from the end surface of the substrate W by the processing liquid flowing toward the radially outward direction on the substrate W.

Around the brush BR1, there is a need for washing the particles removed by the brush BR1 away with as large an amount of processing liquid as possible. Therefore, as illustrated in FIG. 1, it may be arranged such that the auxiliary second nozzle 20 is fixed to the head 65 and the processing liquid is discharged around the brush BR1.

### <STEP 4: Rinsing Processing>

Continuously to STEP 3, rinsing processing is implemented. In the substrate cleaning by the brush, normally, deionized water is used both for the brush cleaning and the rinsing processing. Depending on the type of the substrate, in the brush cleaning, a cleaning liquid such as carbonated water of low concentration, weak ozone water, SC1, SC2, and FOM is used, whereas in the rinsing processing, deionized water or carbonated water of low concentration, etc., may be used.

In the rinsing processing, the brush BR1 is moved to a retracted position (not shown) in a periphery around the spin base 70, and a rinse liquid is discharged from the first nozzle 10.

At the same time as or in parallel to discharge of the rinse processing liquid, the rotational speed of the substrate W is changed from “low speed” to “middle speed.” By the actions described above, while the rinse liquid spreads from the rotation center of the substrate W to the outer peripheral direction on the upper surface of the substrate W, dirt generated due to the brush cleaning is washed away from an outer periphery of the substrate W.

### <STEP 5: Drying Processing>

Continuously to STEP 4, drying processing is performed.

In the drying processing of STEP 5, in addition to the chuck pins CB, the chuck pins CA hold the substrate W. That is, the chuck pins are brought into the state schematically shown in FIG. 6. By holding the substrate W by both the chuck pins CA and CB, the substrate W is more stably held.

Next, the rotational speed of the spin base 70 is changed from middle-speed rotation to high-speed rotation. By this, the substrate W held by the chuck pins CA and CB is rotated at high speed, and the rinse liquid remaining on the substrate W is shaken off and dried (spin-dried).

### <STEP 6: Release of Substrate>

After the drying processing of STEP 5 is completed, rotation of the spin base 70 is gradually reduced and the rotation of the spin base 70 is stopped at the end.

After the spin base 70 is stopped, both the chuck pins CA and CB are brought into the opened state. That is, the chuck pins are brought into the state schematically shown in FIG. 5, and the substrate W can be carried out by a transfer mechanism (not shown).

In STEP 6, in parallel to the chuck pins CA and CB being brought into the opened state, the transfer mechanism (not shown) receives the substrate W.

In STEP 6, after this, a hand portion of the transfer mechanism (not shown) comes in between a lower surface of the substrate W and the upper surface of the spin base 70, and prepares for release of the substrate W. After this, both the chuck pins CA and CB are brought into the “opened state.” Thereby, the substrate W is released from the chuck pins and transferred to the hand portion of the transfer mechanism waiting below the substrate W.

### <STEP 7: Carry-Out of Substrate>

After STEP 6, the transfer mechanism receiving the substrate W transfers the substrate W to the outside of the substrate processing apparatus 1 in a state where the substrate W is placed on the hand portion. Thereby, a series of steps to brush-clean the substrate W is ended.

Although the preferred embodiment of the present invention is described above, for implementations of the present invention, various design changes can be made within the range of the matters described in the claims.

For example, in the above preferred embodiment, the substrate processing apparatus 1 includes the chuck pins CA and CB having different structures from each other. However, it may be arranged such that only the chuck pins CB, in other words, only the chuck pins whose height of the upper surfaces is lower than the upper surface of the substrate W when the chuck pins hold the substrate W are provided.

For example, regarding various movement mechanisms such as an arm movement mechanism, a chuck rotation mechanism, a chuck pin controller, and a spinning mechanism, structures of an arm and a head, a structure of a spin chuck, a structure of chuck pins, etc., in the above description of the preferred embodiment of the present invention, various realization modes are known, and those who are skilled in the art can apply the present invention within the range of the matters described in the claims.

Regarding specific aspects of storage of control information and control for opening/closing the chuck pins, upward/downward moving and horizontally moving the head, etc., various design changes can be made within the range of the matters described in the claims.

Otherwise, various changes can be made for implementations within the range of the matters described in the claims.

The present application corresponds to Japanese Patent Application No. 2017-061401 filed on Mar. 27, 2017 in the Japan Patent Office, and the entire disclosure of this application is incorporated herein by reference.

While the preferred embodiment of the present invention has been described in detail above, these are merely specific examples used to clarify the technical contents of the present invention, and the present invention should not be interpreted as being limited to these specific examples, and the scope of the present invention shall be limited only by the appended claims.

### DESCRIPTION OF REFERENCE SIGNS

W: Substrate
1: Substrate processing apparatus
10: First nozzle
10A: Discharge port
20: Second nozzle
20A: Discharge port
25: Fixing tool
60: Arm movement mechanism
61: Mover portion
61A: Axis rotation mechanism
61B: Elevating/lowering mechanism
62: Cover
63: Support shaft
64: Arm
65: Head
BR1: Brush
50: Spin chuck
52: Support shaft
53: Spin base rotation mechanism
AX: Spin base rotation axis
70: Spin base
75: Chuck pin movement mechanism
75A, 75B: Chuck pin movement mechanism
CA, CB: Chuck pin
CA1, CB1: Chuck pin main body
CA2, CB2: Abutting surface
CA3, CB3: Support shaft
CA4, CA4: Slot
100: Controller
110: Storage unit
121: Processing liquid supply mechanism control unit
122: Arm movement mechanism control unit
123: Chuck pin movement mechanism control unit
124: Spin base rotation mechanism control unit
125: Other-mechanism control unit
200: Processing liquid supply mechanism
210, 220: Pipe
215, 225: On-off valve
211, 221: Flow rate adjustment valve
P1, P2: Pump
250: Tank

1. A substrate processing apparatus that performs brush cleaning of a substrate, comprising:
a spin base provided rotatably about a rotation axis;
a spin base rotation mechanism that rotates the spin base; and
a plurality of first chuck pins provided in the spin base, the first chuck pins being switchable between an opened state and a closed state and capable of clamping an end portion of the substrate from a side surface thereof in the closed state, wherein
an upper surface of each of the plurality of first chuck pins has a height the same as or lower than an upper surface of the substrate in the closed state in which the end portion of the substrate is clamped.

2. The substrate processing apparatus according to claim 1, further comprising:
a plurality of second chuck pins provided in the spin base, the second chuck pins being switchable between an opened state and a closed state and capable of clamping an end portion of the substrate from a side surface thereof in the closed state, wherein
an upper surface of each of the plurality of second chuck pins has a height higher than the upper surface of the substrate in the closed state in which the end portion of the substrate is clamped.

3. The substrate processing apparatus according to claim 1-er-2, wherein
each of the first chuck pins has an abutting surface to be abutted with the substrate in the closed state, and the abutting surface is abuttable with at least a lower surface and a side surface of a peripheral edge portion of the substrate.

4. A substrate processing method that performs brush cleaning of a substrate, comprising:
a first clamping step of clamping the substrate by a plurality of first chuck pins provided in a spin base, the first chuck pins being switchable between an opened state and a closed state and capable of clamping an end portion of the substrate from a side surface thereof in the closed state; and
a second clamping step of clamping the substrate by a plurality of second chuck pins provided in the spin base, the second chuck pins being switchable between an opened state and a closed state and capable of clamping an end portion of the substrate from a side surface thereof in the closed state, wherein
an upper surface of each of the plurality of first chuck pins has a height the same as or lower than an upper surface of the substrate in the closed state in which the end portion of the substrate is clamped, and
an upper surface of each of the plurality of second chuck pins has a height higher than the upper surface of the substrate in the closed state in which the end portion of the substrate is clamped.

5. The substrate processing method according to claim 4, wherein
in the first clamping step, substrate cleaning is performed by a brush.

6. The substrate processing method according to claim 4, wherein
in the first clamping step, the spin base is rotated at first rotational speed, and
in the second clamping step, the spin base is rotated at rotational speed higher than the first rotational speed.

7. A program recording medium of a program to execute a substrate processing method that performs brush cleaning of a substrate, wherein
the substrate processing method comprises:
a first clamping step of clamping the substrate by a plurality of first chuck pins provided in a spin base, the first chuck pins being switchable between an opened state and a closed state and capable of clamping an end portion of the substrate from a side surface thereof in the closed state; and
a second clamping step of clamping the substrate by a plurality of second chuck pins provided in the spin base, the second chuck pins being switchable between an opened state and a closed state and capable of clamping an end portion of the substrate from a side surface thereof in the closed state, wherein
an upper surface of each of the plurality of first chuck pins has a height the same as or lower than an upper surface of the substrate in the closed state in which the end portion of the substrate is clamped, and
an upper surface of each of the plurality of second chuck pins has a height higher than the upper surface of the substrate in the closed state in which the end portion of the substrate is clamped.

8. The program recording medium according to claim 7, wherein
in the first clamping step, substrate cleaning is performed by a brush.

9. The program recording medium according to claim 7, wherein
in the first clamping step, the spin base is rotated at first rotational speed, and
in the second clamping step, the spin base is rotated at rotational speed higher than the first rotational speed.
